(19) United States
(12) Patent Application Publication
(10) Pub. No.: US 2024/0182252 A1
(43) Pub. Date: Jun. 6, 2024

(54) TRANSFER MODULE AND TRANSFER METHOD

(71) Applicant: Tokyo Electron Limited, Tokyo (JP)

(72) Inventors: Toshiaki TOYOMAKI, Miyagi (JP); Norihiko AMIKURA, Miyagi (JP); Seiichi KAISE, Miyagi (JP); Masatomo KITA, Miyagi (JP)

(73) Assignee: Tokyo Electron Limited, Tokyo (JP)

(21) Appl. No.: 18/525,935

(22) Filed: Dec. 1, 2023

(30) Foreign Application Priority Data
Dec. 1, 2022 (JP) 2022-192859
Oct. 30, 2023 (JP) 2023-185339

(51) Int. Cl. B65G 47/90

(52) U.S. Cl. CPC B65G 47/904; B65G 2201/0297

(57) ABSTRACT

There is a transfer module comprising: a housing; a load port disposed on a sidewall of the housing, the load port being capable of placing a container accommodating multiple objects to be transferred; a transfer device disposed in the housing and configured to transfer the objects; and a storage unit disposed in the housing and configured to temporarily accommodate the objects, wherein the housing includes: a first sidewall to which a load-lock module is connected; and a second sidewall other than a sidewall facing the first sidewall, to which the load port is connected, wherein the transfer device has a first arm having multiple forks on which the objects are placed, and the transfer device collectively transfers the objects in the container placed on the load port into the storage unit using the first arm.

### CROSS-REFERENCE TO RELATED APPLICATIONS

This application claims priority to Japanese Patent Application Nos. 2022-192859 filed on Dec. 1, 2022 and 2023-185339 filed on Oct. 30, 2023, the entire contents of each are incorporated herein by reference.

### TECHNICAL FIELD

Various aspects and embodiments of the present disclosure relate to a transfer module and a transfer method.

### BACKGROUND

Japanese Laid-open Patent Publication No. 2021-141136 discloses that “the substrate processing system 1 includes a main body 10 and a controller 100 that controls the main body 10. The main body 10 includes a vacuum transfer module 11, multiple substrate processing modules 12, multiple loads-lock modules 13, multiple storage modules 14, and a substrate aligner module 15. The main body 10 further includes an edge ring (ER) aligner module 16, an atmospheric transfer module 17, and multiple load ports 18.”

### SUMMARY

The present disclosure provides a transfer module and a transfer method capable of reducing an installation area of a substrate processing system.

In accordance with an exemplary embodiment of the present disclosure, there is a transfer module comprising: a housing; a load port disposed on a sidewall of the housing, the load port being capable of placing a container accommodating multiple objects to be transferred; a transfer device disposed in the housing and configured to transfer the objects to be transferred; and a storage unit disposed in the housing and configured to temporarily accommodate the objects to be transferred, wherein the housing includes: a first sidewall to which a load-lock module is connected; and a second sidewall other than a sidewall facing the first sidewall, to which the load port is connected, wherein the transfer device has a first arm having multiple forks on which a plurality of the objects to be transferred are placed, and the transfer device collectively transfers the plurality of the objects in the container placed on the load port into the storage unit using the first arm.

### BRIEF DESCRIPTION OF THE DRAWINGS

FIG. 1 is a schematic plan view showing an example of a substrate processing system in a first embodiment.

FIG. 2 is a schematic cross-sectional view showing an example of a II-II cross section of the substrate processing system illustrated in FIG. 1.

FIG. 3 is a schematic cross-sectional view showing an example of a III-III cross section of the substrate processing system illustrated in FIG. 2.

FIG. 4 is a flowchart showing an example of a substrate transfer method in the first embodiment.

FIGS. 5 to 10 show examples of a substrate transfer process in the first embodiment.

FIG. 11 shows another example of a storage unit.

FIG. 12 is a cross-sectional view taken along a line XII-XII of the storage unit illustrated in FIG. 11.

FIG. 13 is a schematic plan view showing an example of a substrate processing system in a second embodiment.

FIG. 14 is a schematic cross-sectional view showing an example of a XIV-XIV cross section of the substrate processing system illustrated in FIG. 13.

FIG. 15 is a schematic cross-sectional view showing an example of a XV-XV cross section of the substrate processing system illustrated in FIG. 14.

FIG. 16 is a schematic plan view showing an example of a substrate processing system in a third embodiment.

FIG. 17 is a schematic cross-sectional view showing an example of a XVII-XVII cross section of the substrate processing system illustrated in FIG. 16.

FIG. 18 is a schematic cross-sectional view showing an example of a XVIII-XVIII cross section of the substrate processing system illustrated in FIG. 17.

FIG. 19 is a schematic plan view showing another example of the substrate processing system in the third embodiment.

FIG. 20 is a schematic plan view showing an example of a substrate processing system in a fourth embodiment.

FIG. 21 is a schematic cross-sectional view showing an example of a XXI-XXI cross section of the substrate processing system illustrated in FIG. 20.

### DETAILED DESCRIPTION

Hereinafter, embodiments of a transfer module and a transfer method will be described in detail with reference to the accompanying drawings. The following embodiments are not intended to limit the transfer module and the transfer method of the present disclosure.

In order to increase the number of substrates that can be processed per unit time, it is considered to increase the number of processing modules with respect to substrates. When the number of processing modules increases, a substrate processing system including multiple processing modules is scaled up. When the substrate processing system is scaled up, the installation area (footprint) of the substrate processing system in the equipment such as a clean room becomes large, which makes it difficult to arrange multiple substrate processing systems. Therefore, it is required to reduce the installation area of the substrate processing system.

Therefore, the present disclosure provides a technique capable of reducing the installation area of the substrate processing system.

### First Embodiment

### <Configuration of Substrate Processing System 1>

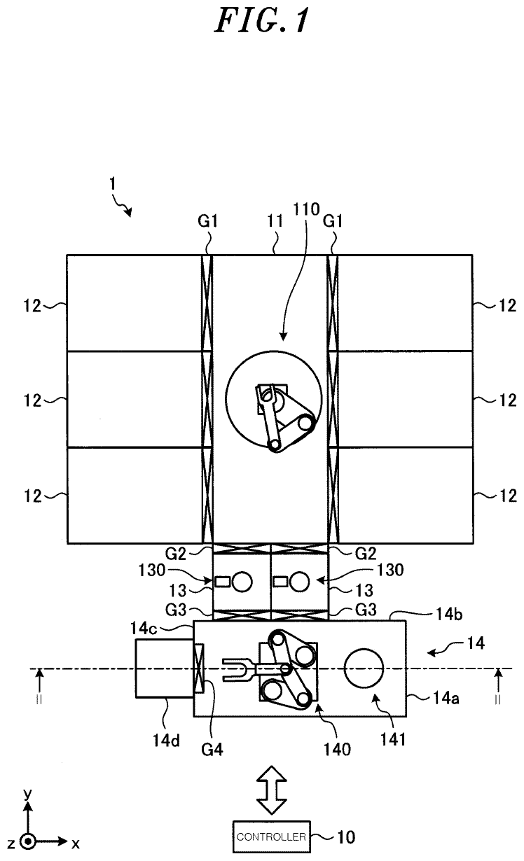

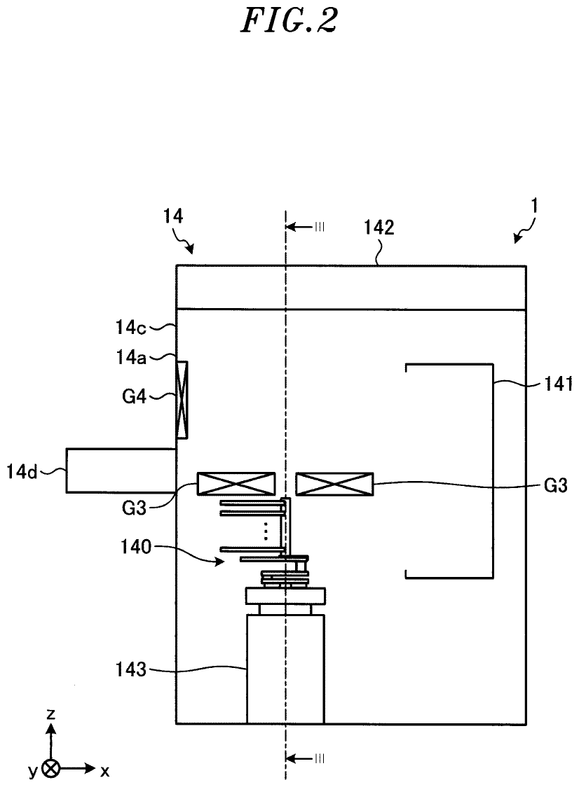

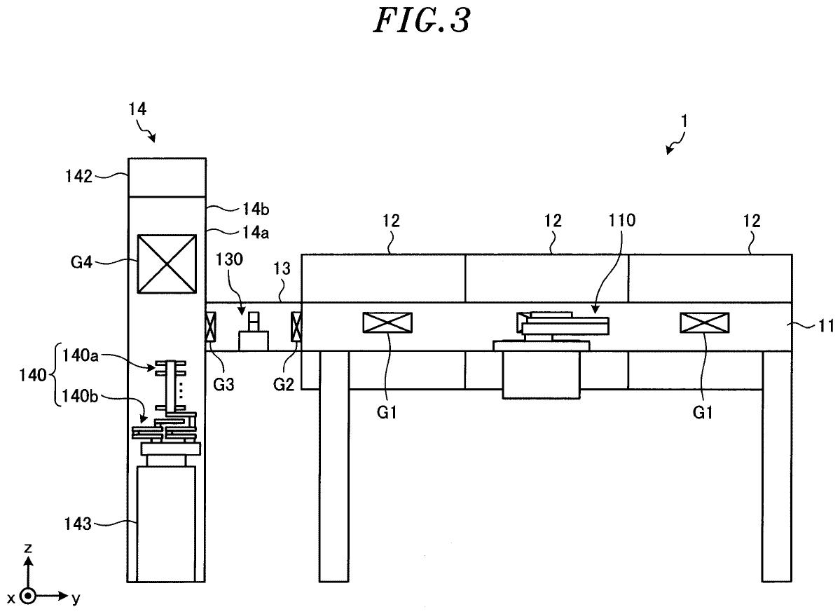

FIG. 1 is a plan view showing an example of a configuration of a substrate processing system 1 according to a first embodiment. FIG. 2 is a schematic cross-sectional view showing an example of a II-II cross section of the substrate processing system 1 illustrated in FIG. 1. FIG. 3 is a schematic cross-sectional view showing an example of a III-III cross section of the substrate processing system 1 illustrated in FIG. 2. In FIG. 1, for convenience, some internal components of the apparatus are illustrated transparently.

As shown in FIG. 1, the substrate processing system 1 includes, for example, a vacuum transfer module (VTM) 11, multiple processing modules (PMs) 12, and multiple load-lock modules (LLMs) 13, and an equipment front end module (EFEM) 14. The EFEM 14 is an example of a transfer module. In the example of FIG. 1, the VTM 11 extends in the Y-axis direction of FIG. 1, and the PMs 12 are arranged adjacent to the VTM 11 in the X-axis direction of FIG. 1. Further, in the example of FIG. 1, the VTM 11, the LLMs 13, and the EFEM 14 are arranged adjacent to each other in the Y-axis direction of FIG. 1.

The PMs 12 are connected to a sidewall of the VTM 11 through gate valves G1. Each PM 12 performs processing such as etching or film formation on a substrate W to be processed. In the example of FIG. 1, six PMs 12 are connected to the VTM 11, but the number of PMs 12 connected to the VTM 11 may be more than six or may be less than six.

A transfer robot 110 is disposed in the VTM 11. The transfer robot 110 transfers the substrate W between the PM 12 and the LLM 13. The inside of the VTM 11 is maintained at a low pressure atmosphere lower than an atmospheric pressure. The substrate W is an example of an object to be transferred.

The LLMs 13 are connected to another sidewall of the VTM 11 through gate valves G2. The LLMs 13 are connected to the EFEM 14 through gate valves G3. An aligner unit 130 for adjusting the orientation of the substrate W is disposed in each LLM 13. In the example of FIG. 1, two LLMs 13 are connected to the VTM 11, but the number of LLMs 13 connected to the VTM 11 may be more than two or may be less than two.

In each LLM 13, after the substrate W is loaded into the LLM 13 from the EFEM 14 through the gate valve G3, the gate valve G3 is closed. Then, the pressure in the LLM 13 is decreased from an atmospheric pressure to a predetermined vacuum level. Then, the gate valve G2 is opened, and the substrate W in the LLM 13 is transferred into the VTM 11 by the transfer robot 110.

Further, in each LLM 13, the substrate W is loaded into the LLM 13 from the VTM 11 by the transfer robot 110 in a state where the pressure in the LLM 13 is maintained at a predetermined vacuum level, and the gate valve G2 is closed. Then, the pressure in the LLM 13 is increased from a predetermined vacuum level to an atmospheric pressure. Then, the gate valve G3 is opened, and the substrate W in the LLM 13 is transferred into the EFEM 14.

The EFEM 14 has a housing 14a and a load port (LP) 14d. In the EFEM 14, a gate valve G4 and the LP 14d are disposed at a second sidewall 14c other than the sidewall facing a first sidewall 14b of the EFEM 14 to which the LLMs 13 are connected. A container such as a front opening unified pod (FOUP) capable of accommodating multiple substrates W is placed on the LP 14d. A container such as a FOUP is transferred by a container transfer mechanism such as an overhead hoist transport (OHT) or the like, and is placed on the LP 14d.

As described above, in the present embodiment, the LP 14d is disposed at the second sidewall 14c of the EFEM 14 other than the sidewall facing the first sidewall 14b to which the LLMs 13 are connected. Accordingly, the length of the substrate processing system 1 in the Y-axis direction can become shorter than that in the case where the LP 14d is disposed at the sidewall facing the first sidewall 14b. Accordingly, the installation area of the substrate processing system 1 can be reduced.

The EFEM 14 is provided with a transfer robot 140 and a storage unit 141. The transfer robot 140 is an example of a transfer device. The transfer robot 140 can move in the Z-axis direction by a driving part 143. The storage unit 141 temporarily accommodates an unprocessed substrate W.

For example, as shown in FIG. 3, the transfer robot 140 includes a first arm 140a having multiple forks and configured to collectively transfer multiple substrates W, and a second arm 140b having one fork and configured to transfer one substrate W. The first arm 140a transfers unprocessed substrates W from the container set on the LP 14d to the storage unit 141. The second arm 140b transfers an unprocessed substrate W from the storage unit 141 to the LLM 13, and transfers a processed substrate W from the LLM 13 to a container set in the LP 14d.

In the present embodiment, the EFEM 14 is maintained at an airtight state, and an inert gas such as a noble gas or a nitrogen gas is supplied into the EFEM 14, and the inert gas circulates in the EFEM 14. A fan filter unit (FFU) 142 is disposed at an upper portion of the EFEM 14, and an inert gas from which particles and the like are removed is supplied into the EFEM 14 from above, thereby forming a downflow in the EFEM 14. Further, in the present embodiment, the pressure in the EFEM 14 is an atmospheric pressure. However, in another embodiment, the pressure in the EFEM 14 may be controlled to a positive pressure. Accordingly, it is possible to suppress particles and the like from entering the EFEM 14 from the outside.

The substrate processing system 1 is controlled by a controller 10. The controller 10 has a memory, a processor, and an input/output interface. Programs or data such as recipes and the like are stored in the memory. The memory is, for example, a random access memory (RAM), a read only memory (ROM), a hard disk drive (HDD) or a solid state drive (SSD), or the like. The processor executes programs read from the memory, thereby controlling the individual components of the substrate processing system 1 through the input/output interface based on the data such as the recipes and the like stored in the memory. The processor is a central processing unit (CPU), a digital signal process (DSP), or the like.

### <Transfer Method>

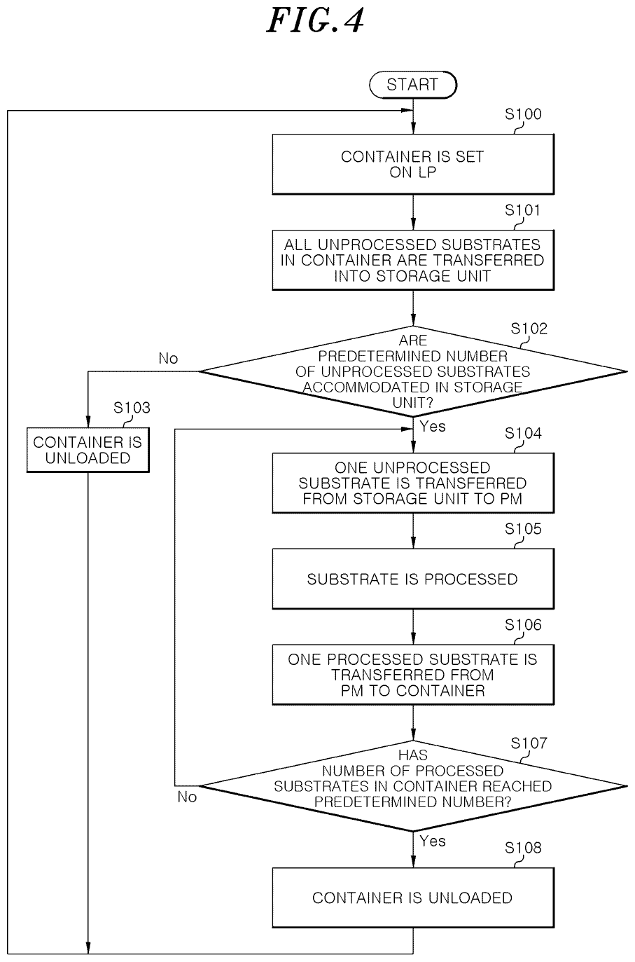

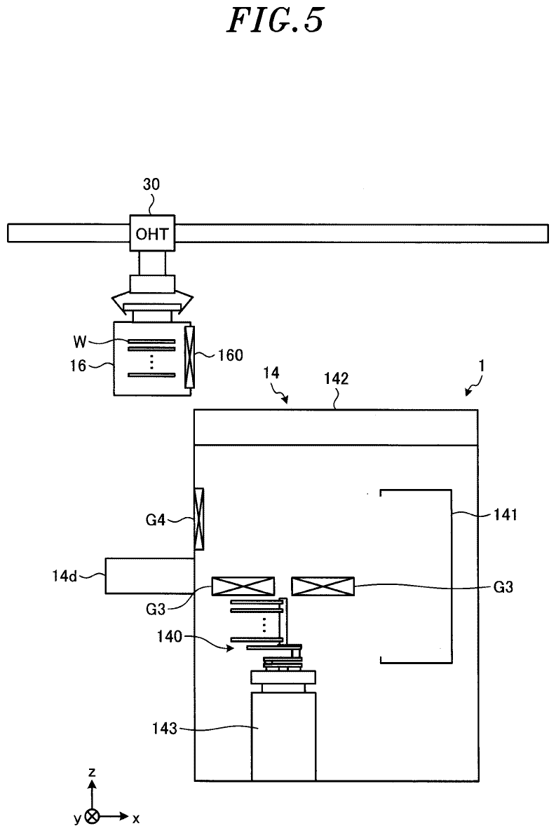

FIG. 4 is a flowchart showing an example of a substrate transfer method in the first embodiment. The processed illustrated in FIG. 4 are realized by controlling individual components of the substrate processing system 1 by the controller 10. Hereinafter, an example of the method for transferring a substrate W illustrated in FIG. 4 will be described with reference to FIGS. 5 to 10.

First, the container 16 accommodating multiple unprocessed substrates W is set on the LP 14d (step S100). In step S100, as shown in FIG. 5, for example, the container 16 accommodating multiple unprocessed substrates W is transferred by a transfer mechanism such as an OHT (Overhead Hoist Transport) 30 or the like, and placed on the LP 14d. Then, a lid 160 of the container 16 and the gate valve G4 are opened.

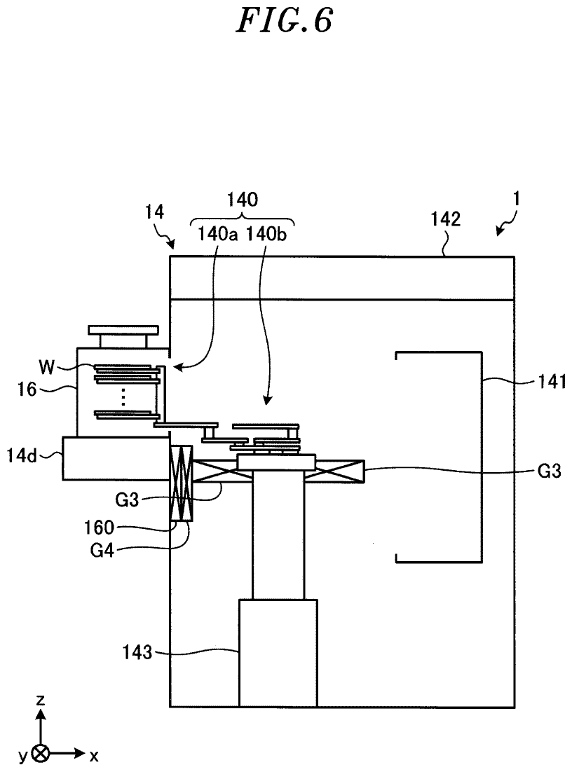

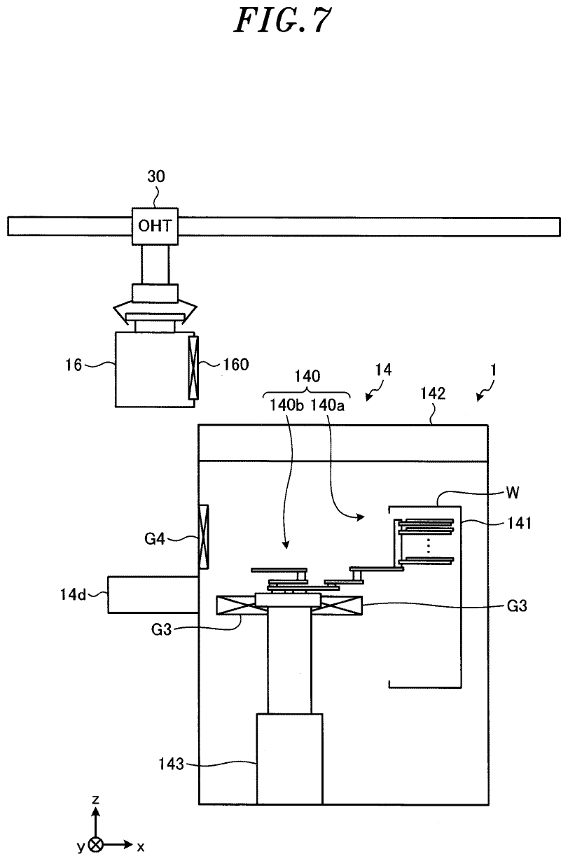

Next, all unprocessed substrates W in the container 16 are transferred into the storage unit 141 by the first arm 140a (step 3101). In step 3101, as shown in FIG. 6, for example, the first arm 140a of the transfer robot 140 enters the container 16, and all unprocessed substrates W are unloaded from the container 16. Then, as shown in FIG. 7, for example, the unprocessed substrates W unloaded from the container 16 are loaded into the storage unit 141 by the first arm 140a.

Next, it is determined whether or not a predetermined number of unprocessed substrates W are accommodated in the storage unit 141 (step S102). In step S102, it is determined whether or not the maximum number of substrates W that can be accommodated in the storage unit 141 are accommodated in the storage unit 141, for example. If a predetermined number of unprocessed substrates W are not accommodated in the storage unit 141 (S102: No), an empty container 16 is unloaded by the transfer mechanism such as the OHT 30 or the like, as shown in FIG. 7, for example (step S103). Then, the process shown in step S100 is executed again.

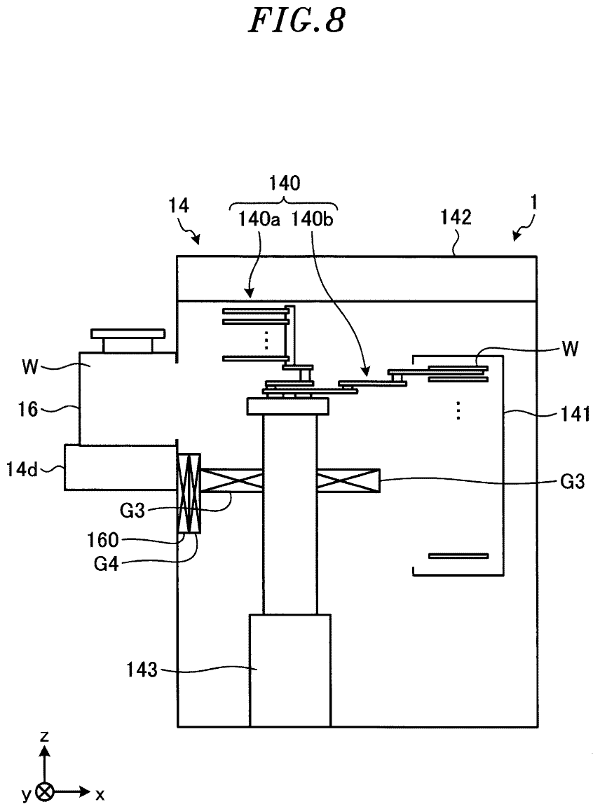

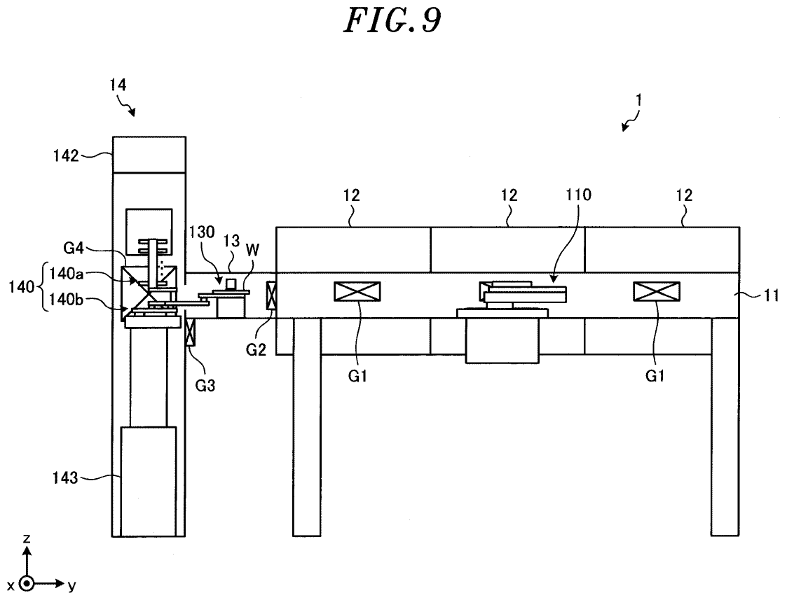

On the other hand, if a predetermined number of unprocessed substrates W are accommodated in the storage unit 141 (S102: Yes), one unprocessed substrate W is transferred from the storage unit 141 to the LLM 13 by the second arm 140b (step S104). In step S104, as shown in FIG. 8, for example, the second arm 140b of the transfer robot 140 enters the storage unit 141, and one unprocessed substrate W is unloaded from the storage unit 141. Then, as shown in FIG. 9, for example, the gate valve G3 is opened, and the unprocessed substrate W is loaded into the LLM 13 by the second arm 140b. After the pressure in the LLM 13 is switched from an atmospheric pressure to a predetermined vacuum level, the gate valve G2 is opened. Then, the unprocessed substrate W loaded into the LLM 13 is unloaded from the LLM 13 and loaded into one of the PMs 12 via the VTM 11 by the transfer robot 110.

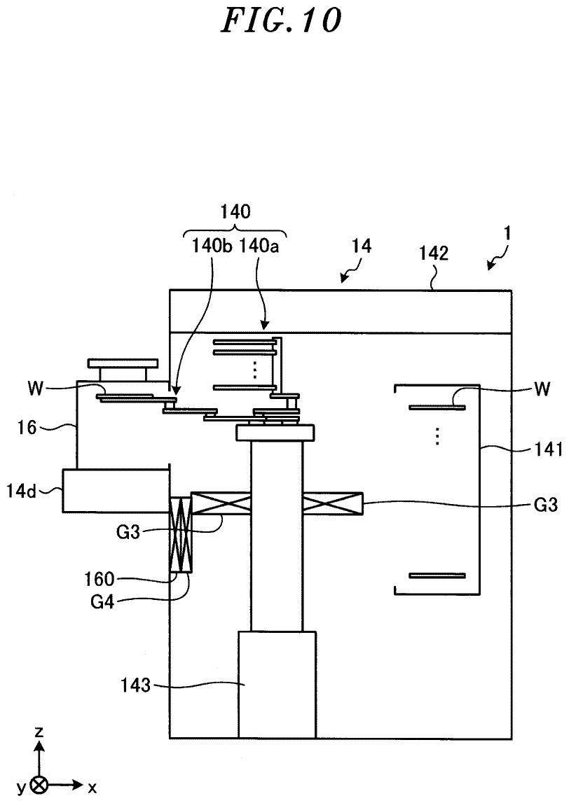

Next, the substrate W is processed by the PM 12 (step S105). Then, the processed substrate W is transferred from the PM 12 to the container 16 by the second arm 140b (step S106). When the processing of the substrate is completed, the gate valve G1 is opened, and the processed substrate W is unloaded from the PM 12 by the transfer robot 110. Then, the processed substrate W is loaded into one of the LLMs 13 via the VTM 11, and the gate valve G2 is closed. Then, the pressure in the LLM 13 is switched from a predetermined vacuum level to an atmospheric pressure. Then, the gate valve G3 is opened, and the processed substrate W is transferred from the LLM 13 into the EF EM 14 by the second arm 140b. Then, the processed substrate W is loaded into the container 16 by the second arm 140b without passing through the storage unit 141, as shown in FIG. 10, for example.

Here, all unprocessed substrates W are unloaded from the container 16 in step S101. Accordingly, it is possible to avoid coexistence of the unprocessed substrate W and the processed substrate W in the container 16, and also possible to suppress adhesion of particles scattered from the processed substrate W to the unprocessed substrate W. Further, in step S106, the processed substrate W is loaded into the container 16 without passing through the storage unit 141. Accordingly, it is possible to avoid coexistence of the unprocessed substrate W and the processed substrate W in the storage unit 141, and also possible to suppress adhesion of particles scattered from the processed substrate W to the unprocessed substrate W.

Next, it is determined whether or not the number of processed substrates W in the container 16 has reached a predetermined number (step S107). In step S17, it is determined whether or not the maximum number of substrates W that can be accommodated in the container 16 are accommodated in the container 16, for example. If the number of processed substrates W in the container 16 has not reached the predetermined number (step S107: No), the process shown in step S104 is executed again.

On the other hand, when the number of processed substrates W in the container 16 has reached the predetermined number (step S107: Yes), the container 16 accommodating the processed substrates W is unloaded from the LP 14d (step S108), and the process shown in step S100 is executed again. In step S108, as shown in FIG. 5, for example, the container 16 accommodating the processed substrate W is unloaded from the LP 14d by the transfer mechanism such as the OHT 30 or the like.

The first embodiment has been described above. As described above, the EF EM 14 of the present embodiment includes the housing 14a, the LP 14d, the transfer robot 140, and the storage unit 141. The LP 14d is disposed on the sidewall of the housing 14a, and can accommodate the container 16 accommodating multiple substrates W. The transfer robot 140 is disposed in the housing 14a, and transfers the substrate W. The storage unit 141 is disposed in the housing 14a, and temporarily accommodates multiple substrates W. The housing 14a has the first sidewall 14b to which the LLMs 13 are connected, and the second sidewall 14c other than a sidewall facing the first sidewall 14b, to which the LP 14d is connected. The transfer robot 140 has the first arm 140a having multiple forks on which multiple substrates W can be placed. Further, the transfer robot 140 collectively transfers multiple substrates W in the container 16 placed on the LP 14d into the storage unit 141 using the first arm 140a.

In the present embodiment, the LP 14d is disposed on the second sidewall 14c of the EFEM 14 other than the sidewall facing the first sidewall 14b to which the LLMs 13 are connected. Accordingly, the length of the substrate processing system 1 in the Y-axis direction can become shorter than that in the case where the LP 14d is disposed on the sidewall facing the first sidewall 14b. Hence, the installation area of the substrate processing system 1 can be reduced.

Here, in the present embodiment, by providing the LP 14d on the second sidewall 14c, the number of containers 16 that can be simultaneously connected to the EFEM 14 becomes smaller than that in the case where the LP 14d is disposed on the sidewall facing the first sidewall 14b.

On the other hand, in the present embodiment, multiple unprocessed substrates W in the container 16 placed on the LP 14d are collectively transferred into the storage unit 141 by the first arm 140a. Accordingly, the unprocessed substrates W in the container 16 can be transferred quickly, and the decrease in throughput due to the decrease in the number of containers 16 simultaneously connected to the EFEM 14 is suppressed. Further, in the present embodiment, multiple unprocessed substrates W in the container 16 placed on the LP 14d are collectively transferred into the storage unit 141 by the first arm 140a. Accordingly, the substrates W accommodated in the storage unit 141 can be quickly processed. Hence, in the present embodiment, the decrease in throughput due to the decrease in the number of containers 16 simultaneously connected to the EFEM 14 is suppressed.

Further, in the above-described first embodiment, the transfer robot 140 has the second arm 140b having one fork on which one substrate W can be placed. The transfer robot 140 transfers one unprocessed substrate W transferred into the storage unit 141 to the LLM 13 using the second arm 140b. Accordingly, the substrates W can be processed one by one.

Further, in the above-described first embodiment, the housing 14a of the EFEM 14 is maintained in an airtight state, and an inert gas circulates in the housing 14a. Accordingly, it is possible to suppress particles and the like from entering the EFEM 14 from the outside.

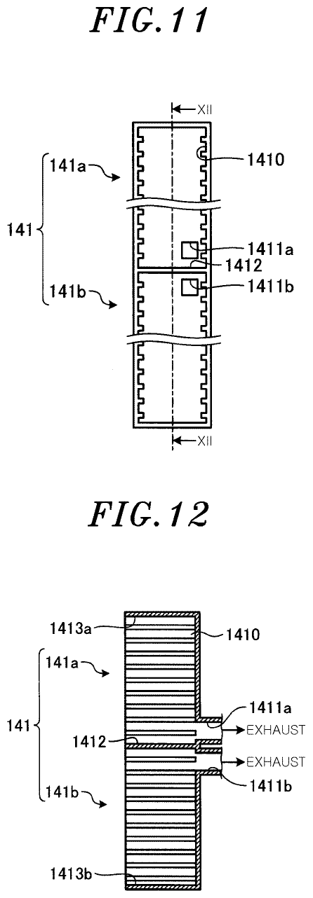

Further, in the above-described first embodiment, only unprocessed substrates W are accommodated in the storage unit 141. However, the technique of the present disclosure is not limited thereto, and processed substrates W may be accommodated in the storage unit 141. However, if the unprocessed substrates W and the processed substrates W coexist in the storage unit 141, particles scattered from the processed substrates W may be adhered to the unprocessed substrates W, which may result in contamination of the unprocessed substrates. Therefore, when the unprocessed substrates W and the processed substrates W are accommodated in the storage unit 141, as shown in FIGS. 11 and 12, for example, it is preferable to separate a space accommodating the unprocessed substrates W and a space accommodating the processed substrates W.

FIG. 11 is a front view showing another example of the storage unit. FIG. 12 is a cross-sectional view taken along a line XII-XII of the storage unit shown in FIG. 11. The storage unit 141 shown in FIGS. 11 and 12 has a first accommodating chamber 141a and a second accommodating chamber 14b that are separated by a partition wall 1412. Multiple recesses 1410 for supporting the substrate W are formed at the sidewalls of the first accommodating chamber 141a and the second accommodating chamber 141b. The first accommodating chamber 141a is disposed above the second accommodating chamber 141b. In the present embodiment, the first accommodating chamber 141a accommodates unprocessed substrates W, and the second accommodating chamber 141b accommodates processed substrates W.

Multiple unprocessed substrates W are collectively transferred from the container 16 into the first accommodating chamber 141a by the first arm 140a, and then transferred from the first accommodating chamber 141a into the LLM 13 by the second arm 140b. Further, the processed substrates W are transferred from the LLM 13 into the second accommodating chamber 141b by the second arm 140b, and then the processed substrates are transferred from the second accommodating chamber 141b into the container 16 by the first arm 140a.

The first accommodating chamber 141a has a first opening 1413a for loading and unloading the substrate W, and a first exhaust port 1411a for exhausting a gas in the first accommodating chamber 141a is formed at the sidewall facing the first opening 1413a. An exhaust device (not shown) is connected to the first exhaust port 1411a through an exhaust line. Accordingly, gas flow directed from the first opening 1413a toward the first exhaust port 1411a is formed, and the scattering of particles from the substrate W accommodated in the first accommodating chamber 141a into the EFEM 14 is suppressed.

The second accommodating chamber 141b has a second opening 1413b for loading and unloading the substrate W, and a second exhaust port 1411b for exhausting a gas in the second accommodating chamber 141b is formed at the sidewall facing the second opening 1413b. An exhaust device (not shown) is connected to the second exhaust port 1411b through an exhaust line. Accordingly, gas flow directed from the second opening 1413b toward the second exhaust port 1411b is formed, and the scattering of particles from the substrate W accommodated in the second accommodating chamber 141b into the EFEM 14 is suppressed.

Further, in the present embodiment, the unprocessed substrates W are accommodated in the first accommodating chamber 141a, and the processed substrates W are accommodated in the second accommodating chamber 141b disposed below the first accommodating chamber 141a. Accordingly, it is possible to suppress the adhesion of particles that have fallen from the processed substrate W during the loading/unloading of the processed substrate W into/from the storage unit 141 to the unprocessed substrate W.

The first accommodating chamber 141a accommodating the unprocessed substrates W may not be provided with the first exhaust port 1411a. Accordingly, the intrusion of particles floating in the EFEM 14 into the first accommodating chamber 141a through the first opening 1413a is suppressed.

### Second Embodiment

### <Configuration of Substrate Processing System 1>

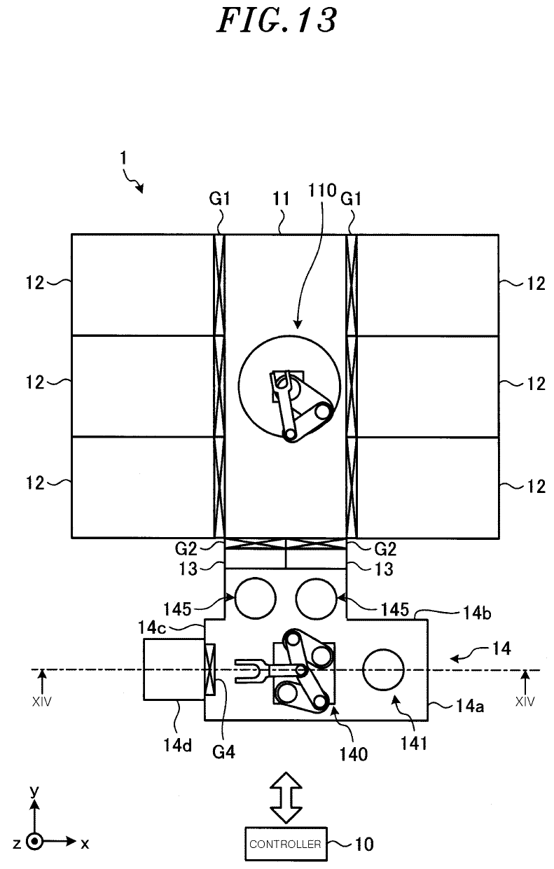

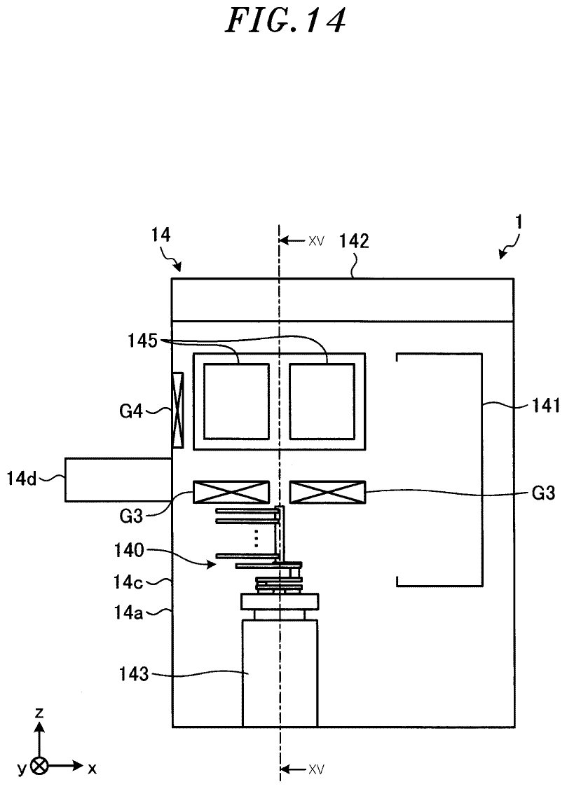

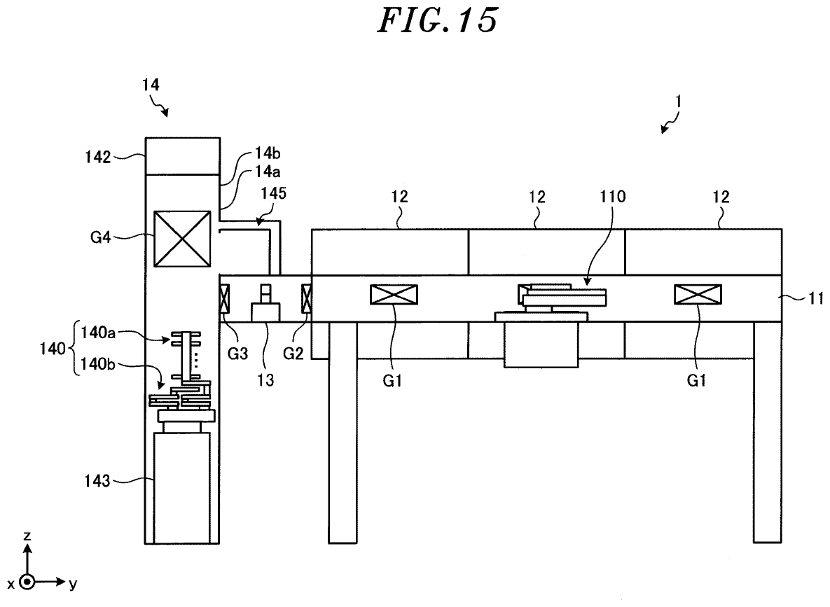

FIG. 13 is a schematic plan view showing an example of a substrate processing system 1 in a second embodiment. FIG. 14 is a schematic cross-sectional view showing an example of an XIV-XIV cross section of the substrate processing system 1 illustrated in FIG. 13. FIG. 15 is a schematic cross-sectional view showing an example of a XV-XV cross section of the substrate processing system 1 illustrated in FIG. 14. The components in FIGS. 13 to 15 denoted by like reference numerals as those in FIGS. 1 to 3 have the same or similar functions as those of the components in FIGS. 1 to 3 except the following characteristics, so that the description thereof will be omitted.

In the substrate processing system 1 of the present embodiment, as shown in FIGS. 13 to 15, for example, a part of the first sidewall 14b of the EFEM 14 to which the LLMs 13 are connected protrudes to a position higher than the LLMs 13. Further, in the EFEM 14, storage units 145 are disposed at the position higher than the LLMs 13.

Accordingly, a larger number of unprocessed substrates W can be accommodated in the EFEM 14, and the decrease in throughput due to the decrease in the number of containers 16 simultaneously connected to the EFEM 14 can be further suppressed. In the example shown in FIGS. 13 to 15, two storage units 145 are disposed in the EFEM 14 to be located higher than the LLMs 13, but the number of storage units 145 disposed in the EFEM 14 to be located higher than the LLMs 13 may be one or may be more than two.

### Third Embodiment

### <Configuration of Substrate Processing System 1>

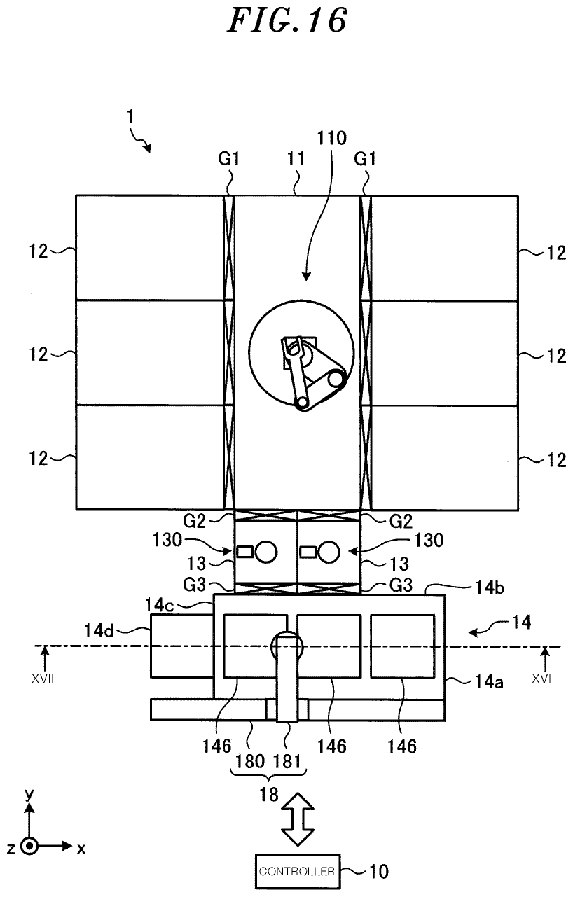

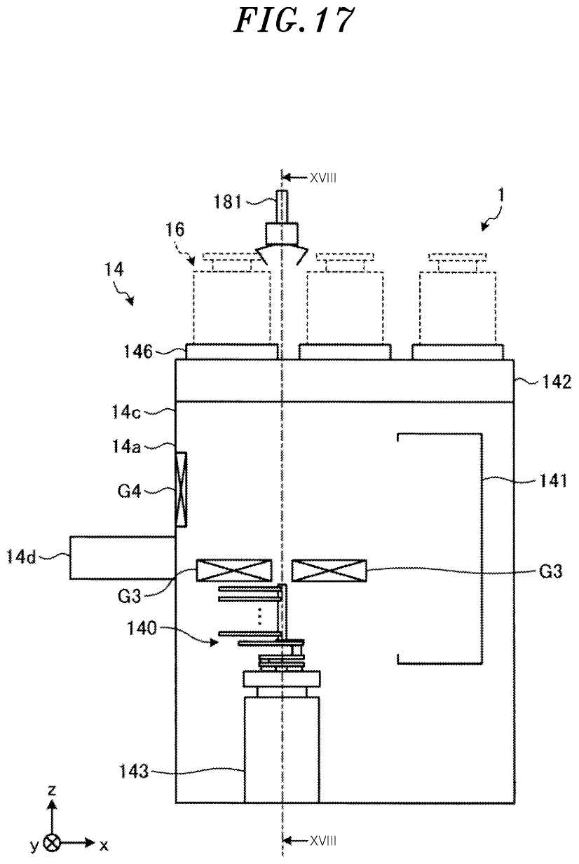

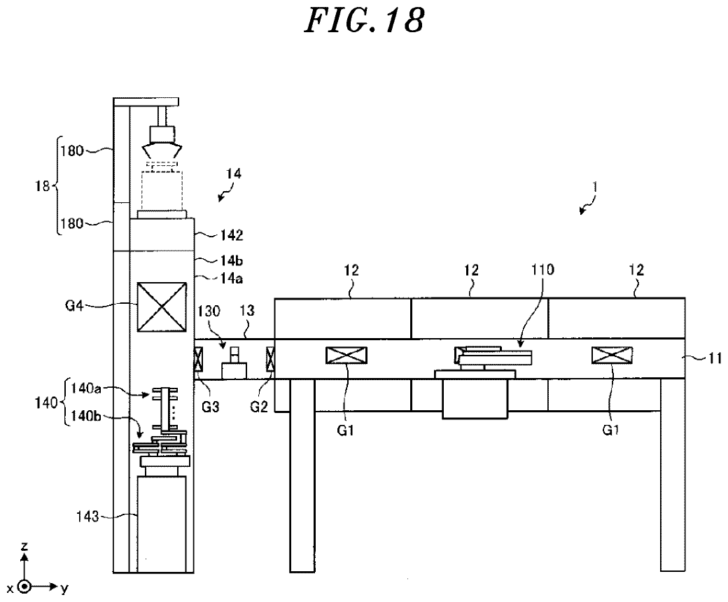

FIG. 16 is a schematic plan view showing an example of a substrate processing system 1 in a third embodiment. FIG. 17 is a schematic cross-sectional view showing an example of a XVII-XVII cross section of the substrate processing system 1 illustrated in FIG. 16. FIG. 18 is a schematic cross-sectional view showing an example of a XVIII-XVIII cross section of the substrate processing system 1 illustrated in FIG. 17. The components in FIGS. 16 to 18 denoted by like reference numerals as those in FIGS. 1 to 3 have the same or similar functions as those of the components in FIGS. 1 to 3 except the following characteristics, so that the description thereof will be omitted.

In the present embodiment, multiple stages 146 on which the containers 16 are temporarily placed by the OHT 30 are disposed on the EFEM 14, as shown in FIGS. 16 to 18, for example. Further, a transfer mechanism 18 is disposed at the sidewall of the EFEM 14. The transfer mechanism 18 includes a guide rail 180 and a crane 181. The crane 181 moves along the guide rail 180, and moves the container 16 between the stage 146 and the LP 14d.

The container 16 containing the unprocessed substrates W is transferred and placed on the stage 146 by the OHT 30. The crane 181 transfers the container 16 placed on the stage 146 onto the LP 14d. The container 16 containing the processed substrates W may be unloaded from the LP 14d by the OHT 30, or may be transferred from the position higher than the LP 14d onto the stage 146 by the crane 181 and then unloaded from the stage 146 by the OHT 30.

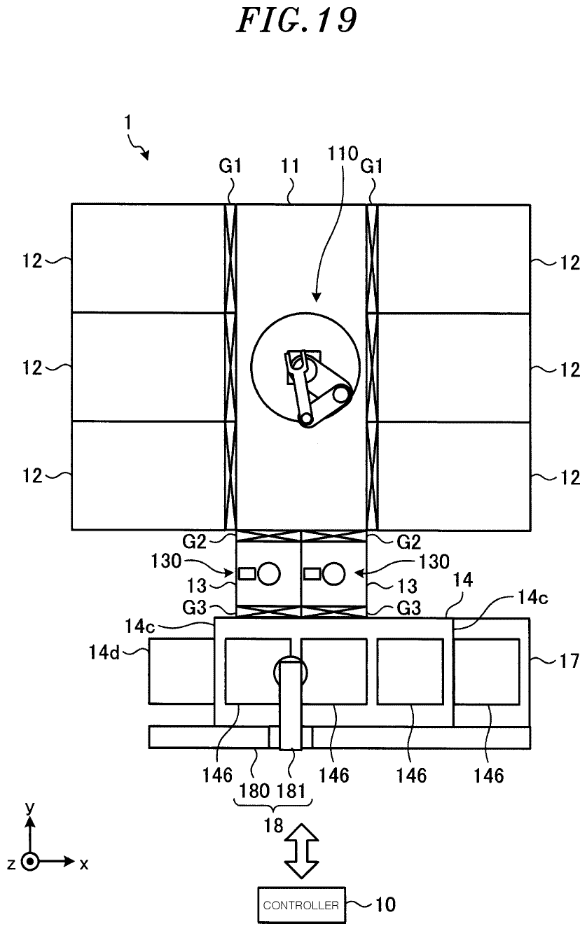

As shown in FIG. 19, for example, a utility unit 17 in which electrical wiring, gas lines, and the like are arranged may be disposed near the second sidewall 14c of the EFEM 14, and the stage 146 may also be disposed above the utility unit 17. The utility unit 17 is an example of an equipment accommodating chamber.

### Fourth Embodiment

### <Configuration of Substrate Processing System 1>

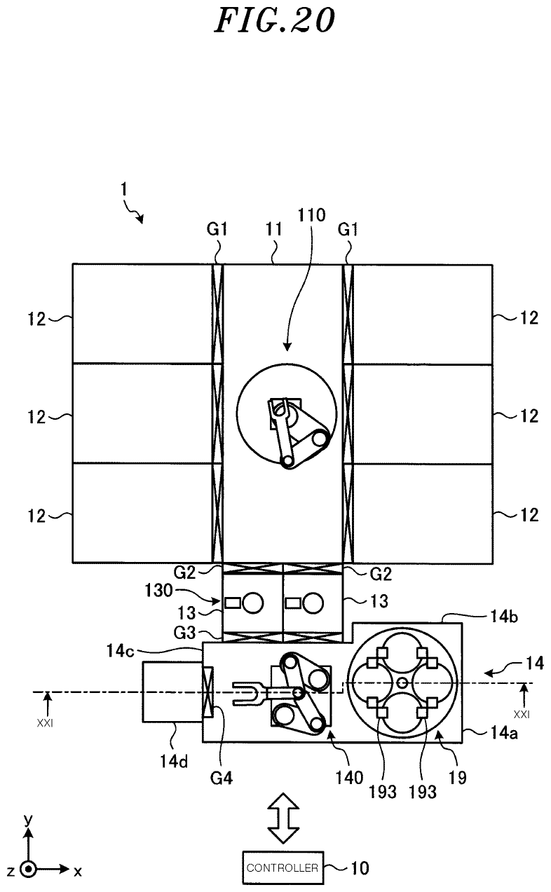

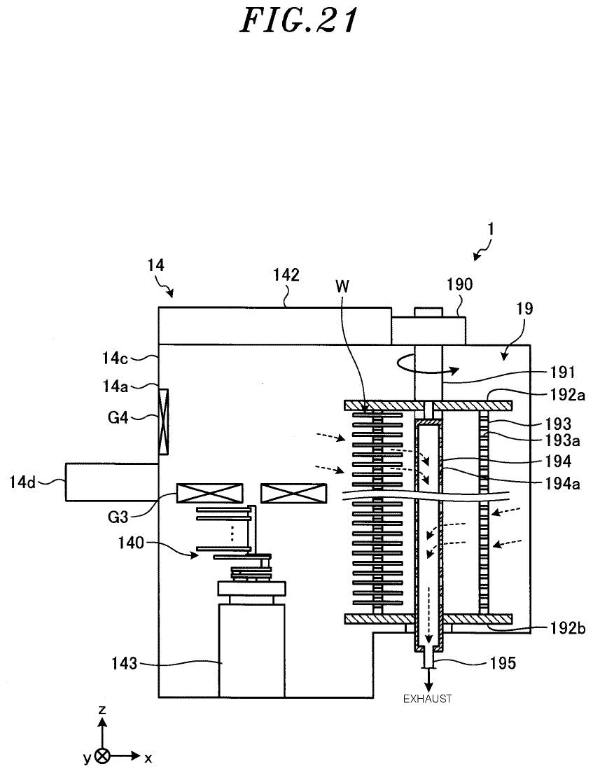

FIG. 20 is a schematic plan view showing an example of a substrate processing system 1 in a fourth embodiment. FIG. 21 is a schematic cross-sectional view showing an example of a XXI-XXI cross section of the substrate processing system 1 illustrated in FIG. 20. The components in FIGS. 20 and 21 denoted by like reference numerals as those in FIGS. 1 to 3 have the same or similar functions as those of the components in FIGS. 1 to 3 except the following characteristics, so that the description thereof will be omitted.

The EFEM 14 of the present embodiment is provided with a storage unit 19. For example, as shown in FIG. 21, the storage unit 19 includes a driving part 190, a shaft 191, a first rotation plate 192a, a second rotation plate 192b, substrate holders 193, and a rotation axis 194. The substrate holder 193 has multiple recesses 193a for supporting the substrates W, and a pair of the substrate holders 193 support the substrate W. The first rotation plate 192a is configured to support one end of each substrate holder 193. The second rotation plate 192b is configured to support the other end of each substrate holder 193.

The rotation shaft 194 is configured to support the first rotation plate 192a and the second rotation plate 192b to be rotatable. Further, the rotation axis 194 is fixed to the shaft 191. The driving part 190 is configured to rotate the shaft 191. When the driving part 190 rotates the shaft 191, the rotation axis 194 rotates, and the substrate holders 193 supported by the first rotation plate 192a and the second rotation plate 192b also rotate about the rotation shaft 194.

For example, when multiple unprocessed substrates W are collectively transferred from the container 16 into the storage unit 19 by the first arm 140a, the driving part 190 rotates the shaft 191 such that a pair of substrate holders 193 where the substrate W is not accommodated becomes close to the transfer robot 140. Further, when the substrate W transferred into the LLM 13 by the second arm 140b is unloaded from the storage unit 19, the driving part 190 rotates the shaft 191 such that a pair of substrate holders 193 where the substrate W is accommodated becomes close to the transfer robot 140. Accordingly, the storage unit 19 can accommodate a larger number of substrates W, and the decrease in throughput due to the decrease in the number of containers 16 simultaneously connected to the EFEM 14 can be further suppressed.

Further, in the present embodiment, the rotation shaft 194 has a cylindrical shape, and multiple through-holes 194a are formed on the surface of the rotation shaft 194. A gas in the space in the rotation shaft 194 is exhausted through an exhaust line 195 by an exhaust device (not shown). Accordingly, gas flow can be formed between the multiple substrates W accommodated in the substrate holders 193, and the adhesion of particles or the like to the substrates W accommodated in the storage unit 19 can be suppressed.

### <Other Applications>

The technique of the present disclosure is not limited to the above-described embodiments, and various modifications can be made within the scope of the gist thereof.

For example, in the above-described embodiments, the aligner unit 130 is disposed in the LLM 13. However, the present disclosure is not limited thereto. In another embodiment, the aligner unit 130 may be disposed in the VTM 11. Alternatively, in the EFEM 14 of the above-described second embodiment, the aligner unit 130 may be provided instead of any one of the two storage units 145 disposed above the LLM 13.

Although the above embodiments have described the EFEM 14 for transferring the unprocessed substrates W and the processed substrates W, the technique of the present disclosure is not limited thereto. In another embodiment, the EFEM 14 may transfer consumable parts to be used in the PMs 12. The consumable parts to be used in the PM 12 include, for example, an electrostatic chuck that attracts and supports a substrate W, an edge ring disposed at the electrostatic chuck, an upper electrode, and the like. When the consumable parts are accommodated in the storage unit 141 or 145, the storage unit 141 or 145 may store consumable parts that have been used at least once as well as unused consumable parts.

Further, it should be noted that the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

Further, the following appendices are disclosed with respect to the above embodiments.

### APPENDIX 1

A transfer module comprising:
a housing;
a load port disposed on a sidewall of the housing, the load port being capable of placing a container accommodating multiple objects to be transferred;
a transfer device disposed in the housing and configured to transfer the objects to be transferred; and
a storage unit disposed in the housing and configured to temporarily accommodate the objects to be transferred,
wherein the housing includes:
a first sidewall to which a load-lock module is connected; and
a second sidewall other than a sidewall facing the first sidewall, to which the load port is connected,
wherein the transfer device has a first arm having multiple forks on which a plurality of the objects to be transferred are placed, and
the transfer device collectively transfers the plurality of the objects in the container placed on the load port into the storage unit using the first arm.

### APPENDIX 2

The transfer module of Appendix 1, wherein the transfer device further has a second arm having one fork on which one object to be transferred is placed, and
the transfer device transfers one object to be transferred into the storage unit, to the load-lock module using the second arm.

### APPENDIX 3

The transfer module of Appendix 2, wherein the storage unit includes:
a first accommodating chamber; and
a second accommodating chamber,
the transfer device collectively transfers the objects to be transferred from the container into the first accommodating chamber using the first arm, transfers one object to be transferred from the first accommodating chamber into the load-lock module using the second arm, transfers one object to be transferred from the load-lock module to the second accommodating chamber using the second arm, and collectively transfers the objects to be transferred from the second accommodating chamber into the container using the first arm.

### APPENDIX 4

The transfer module of Appendix 3, wherein the first accommodating chamber includes:
a first opening through which the object to be transferred object is loaded and unloaded; and
a first exhaust port configured to exhaust a gas flowing in from the first opening, and
the second accommodating chamber includes:
a second opening through which the object to be transferred is loaded and unloaded; and
a second exhaust port configured to exhaust a gas flowing in from the second opening.

### APPENDIX 5

The transfer module of any one of Appendices 1 to 4, further comprising:
a plurality of the storage units,
wherein a part of the first sidewall of the housing protrudes to a position above the load-lock module, and
some of the plurality of the storage units are disposed in the housing above the load-lock module.

### APPENDIX 6

The transfer module of Appendices 1 to 5, further comprising:
multiple stages disposed on an upper surface of the housing, the stage being capable of placing the container; and
a transfer mechanism configured to transfer the container between each of the stages and the load port.

### APPENDIX 7

The transfer module of Appendix 6, wherein the plurality of stages are also disposed on an upper surface of an equipment accommodating chamber that is disposed near the second sidewall and accommodates electrical equipment used in the transfer module.

### APPENDIX 8

The transfer module of Appendices 1 to 7, wherein the housing is maintained at an airtight state, and an inert gas circulates in the housing.

### APPENDIX 9

The transfer module of Appendices 1 to 8, wherein the storage unit includes:
multiple substrate holders configured to accommodate multiple objects to be transferred;
a first rotation plate configured to support one end of each of the substrate holders;
a second rotation plate configured to support the other end of each of the substrate holders;
a rotation shaft configured to support the first rotation plate and the second rotation plate to be rotatable; and
a driving part configured to rotate the rotation shaft.

### APPENDIX 10

The transfer module of Appendix 9, wherein the rotation shaft has a cylindrical shape and multiple through-holes are formed on a sidewall of the rotation shaft, and
a gas in the storage unit is exhausted through the through-holes formed in the rotation shaft.

### APPENDIX 11

A transfer method comprising:
a) collectively transferring multiple objects to be transferred using a first arm of a transfer device from a container accommodating the objects to be transferred into a first accommodating chamber of a storage unit that temporarily stores the objects to be transferred;
b) transferring one object to be transferred from the first accommodating chamber into a load-lock module using a second arm of the transfer device;
c) transferring one object to be transferred from the load-lock module to a second accommodating chamber of the storage unit using the second arm; and
d) collectively transferring the objects to be transferred from the second accommodating chamber into the container using the first arm.

1. A transfer module comprising:
a housing;
a load port disposed on a sidewall of the housing, the load port being capable of placing a container accommodating multiple objects to be transferred;
a transfer device disposed in the housing and configured to transfer the objects to be transferred; and
a storage unit disposed in the housing and configured to temporarily accommodate the objects to be transferred,
wherein the housing includes:
a first sidewall to which a load-lock module is connected; and
a second sidewall other than a sidewall facing the first sidewall, to which the load port is connected,
wherein the transfer device has a first arm having multiple forks on which the objects to be transferred are placed, and
the transfer device collectively transfers the objects in the container placed on the load port into the storage unit using the first arm.

2. The transfer module of claim 1, wherein the transfer device further has a second arm having one fork on which one object to be transferred is placed, and
the transfer device transfers one object to be transferred into the storage unit, to the load-lock module using the second arm.

3. The transfer module of claim 2, wherein the storage unit includes:
a first accommodating chamber; and
a second accommodating chamber,
the transfer device collectively transfers the objects to be transferred from the container into the first accommodating chamber using the first arm, transfers one object to be transferred from the first accommodating chamber into the load-lock module using the second arm, transfers one object to be transferred from the load-lock module to the second accommodating chamber using the second arm, and collectively transfers the objects to be transferred from the second accommodating chamber into the container using the first arm.

4. The transfer module of claim 3, wherein the first accommodating chamber includes:
a first opening through which the object to be transferred object is loaded and unloaded; and
a first exhaust port configured to exhaust a gas flowing in from the first opening, and
the second accommodating chamber includes:
a second opening through which the object to be transferred is loaded and unloaded; and
a second exhaust port configured to exhaust a gas flowing in from the second opening.

5. The transfer module of claim 1, further comprising:
a plurality of the storage units,
wherein a part of the first sidewall of the housing protrudes to a position above the load-lock module, and
some of the plurality of the storage units are disposed in the housing above the load-lock module.

6. The transfer module of claim 1, further comprising:
multiple stages disposed on an upper surface of the housing, the stage being capable of placing the container; and
a transfer mechanism configured to transfer the container between each of the stages and the load port.

7. The transfer module of claim 6, wherein the plurality of stages are also disposed on an upper surface of an equipment accommodating chamber that is disposed near the second sidewall and accommodates electrical equipment used in the transfer module.

8. The transfer module of claim 1, wherein the housing is maintained at an airtight state, and an inert gas circulates in the housing.

9. The transfer module of claim 1, wherein the storage unit includes:
multiple substrate holders configured to accommodate multiple objects to be transferred;
a first rotation plate configured to support one end of each of the substrate holders;
a second rotation plate configured to support the other end of each of the substrate holders;
a rotation shaft configured to support the first rotation plate and the second rotation plate to be rotatable; and
a driving part configured to rotate the rotation shaft.

10. The transfer module of claim 9, wherein the rotation shaft has a cylindrical shape and multiple through-holes are formed on a sidewall of the rotation shaft, and
a gas in the storage unit is exhausted through the through-holes formed in the rotation shaft.

11. A transfer method comprising:
a) collectively transferring multiple objects to be transferred using a first arm of a transfer device from a container accommodating the objects to be transferred into a first accommodating chamber of a storage unit that temporarily stores the objects to be transferred;
b) transferring one object to be transferred from the first accommodating chamber into a load-lock module using a second arm of the transfer device;
c) transferring one object to be transferred from the load-lock module to a second accommodating chamber of the storage unit using the second arm; and
d) collectively transferring the objects to be transferred from the second accommodating chamber into the container using the first arm.
